(19) United States
(12) Patent Application Publication
(10) Pub. No.: US 2026/0013056 A1
(43) Pub. Date: Jan. 8, 2026

(54) DISPLAY PANEL AND DISPLAY DEVICE INCLUDING THE SAME

(71) Applicant: WUHAN CHINA STAR OPTOELECTRONICS SEMICONDUCTOR DISPLAY TECHNOLOGY CO., LTD., Wuhan, Hubei (CN)

(72) Inventor: Wenqiang WANG, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/247,526

(22) PCT Filed: Mar. 24, 2023
(86) PCT No.: PCT/CN2023/083652

§ 371 Date: Sep. 30, 2025

(30) Foreign Application Priority Data
Feb. 23, 2023 (CN) 202310160112.2

(51) Int. Cl. H05K 5/02

(52) U.S. Cl. CPC H05K 5/0217

(57) ABSTRACT

The disclosure provides a display panel and a display device. A first opening includes a hole body part and hole end parts connected to two opposite ends of the hole body part, respectively. The hole body part includes a hole buffer sub-part and a hole connection sub-part connected between the hole end parts and the hole buffer sub-part. A width of the hole connection sub-part is less than a width of the hole end part and a width of the hole buffer sub-part. The hole buffer sub-part in one of two adjacent first opening groups and a side of the hole connection sub-part close to a corresponding one of the hole end parts in the other one of the two adjacent first opening groups are disposed in alignment.

### TECHNICAL FIELD

The disclosure relates to the technical field of display, in particular to a display panel and a display device including the same.

### BACKGROUND

Foldable display panels can solve a contradictory problem between use of large-sized screens and realization of small weight of devices, and give more possibilities for appearance designs and interaction designs of intelligent phones. In recent years, major terminal manufacturers in the field have successively developed foldable display panels applying to the large-sized screens widely favored by users. Specifically, consumption demands of the large-sized screens and miniaturization of the devices can be realized through flattening and folding of foldable display screens.

Mainstream mobile phones using the foldable display screens in market mainly include in-folded mobile phones and out-folded mobile phones, and a technology of in-folded display panels applied to the in-folded mobile phones has been very mature. However, out-folded display screens applied to the out-folded mobile phones are prone to arching, and bending areas of the out-folded display screens are prone to arching and deformation with increase of a number of bending times, resulting in permanent bulging or fracture.

### SUMMARY

### Technical Problem

Embodiments of the disclosure provides a display panel and a display device to improve a buffering effect of a support layer on bending stress, so as to reduce probability of arching and fracture of the support layer.

### Technical Solutions

An embodiment of the disclosure provides a display panel, the display panel includes a bending area and non-bending areas adjoined with the bending area, and the bending area is defined with a quasi-bending line extending along a first direction;
the display panel further includes:
a panel body; and
a support layer, disposed on a side of the panel body, wherein the support layer includes a plurality of first opening groups disposed at the bending area and arranged along a second direction, a preset angle is defined between the first direction and the second direction, and each of the first opening groups includes a plurality of first openings arranged along the first direction and disposed at intervals;
wherein each of the first openings includes a hole body part and hole end parts connected to two opposite ends of the hole body part in the first direction; the hole body part includes at least one hole buffer sub-part and at least one hole connection sub-part which is connected to the hole end parts and the hole buffer sub-part in the first direction, and a width of the hole connection sub-part is less than a width of each of the hole end parts and a width of the hole buffer sub-part in the second direction; and
wherein the hole buffer sub-part in one of two adjacent first opening groups of the first opening groups and a side of the hole connection sub-part close to a corresponding one of the hole end parts in the other one of the two adjacent first opening groups of the first opening groups are disposed in alignment along the second direction.

In an embodiment of the disclosure, the support layer further includes a spacing part disposed between two adjacent first openings of the first openings in one of the first opening groups, and the hole buffer sub-part and the spacing part are staggered along the second direction.

In an embodiment of the disclosure, the hole body part includes two hole buffer sub-parts arranged between two hole end parts along the first direction, and a hole middle sub-part connected between the two hole buffer sub-parts in the first direction, and a width of the hole middle sub-part is less than the width of each of the hole end parts and a width of each of the hole buffer sub-parts in the second direction;
wherein the hole middle sub-part in the one of two adjacent first opening groups and the spacing part of in the other one of the two adjacent first opening groups are disposed in alignment along the second direction.

In an embodiment of the disclosure, each of the first openings includes the two hole end parts, two hole connection sub-parts, the two hole buffer sub-parts, and the hole middle sub-part, and the two hole buffer sub-parts are connected to two opposite sides of the hole middle sub-part, respectively, the two hole connection sub-parts are connected to two opposite sides of the two hole buffer sub-parts away from the hole middle sub-part, respectively, and the two hole end parts are connected to two opposite sides of the two hole connection sub-parts away from the hole middle sub-part, respectively.

In an embodiment of the disclosure, the two hole end parts, the two hole connection sub-parts, and the two hole buffer sub-parts are symmetrically disposed relative to the hole middle sub-part, respectively.

In an embodiment of the disclosure, a width of a side of the hole buffer sub-part close to the hole middle sub-part decreases gradually along a direction of the hole buffer sub-part close to the hole middle sub-part, and a width of a side of the hole buffer sub-part close to the hole connection sub-part decreases gradually along a direction of the hole buffer sub-part away from the hole middle sub-part, and a width of a side of each of the hole end parts close to the hole connection sub-part gradually decreases along a direction of each of the hole end parts close to the hole connection sub-part.

In an embodiment of the disclosure, a ratio of the width of each of the hole end parts in the second direction to a width of the hole connection sub-part in the second direction ranges between 1.5 and 2.5; and
a ratio of the width of each of the hole end parts in the second direction to the width of the hole middle sub-part in the second direction ranges between 1.5 and 2.5.

In an embodiment of the disclosure, a first distance is defined between the hole buffer sub-part in the one of two adjacent first opening groups and the hole connection sub-part in the other one of the two adjacent first opening groups in the second direction, a second distance is defined between the hole connection sub-part in the one of two adjacent first opening groups and the hole connection sub-part in the other one of the two adjacent first opening groups in the second direction, and the hole connection sub-part is defined with a preset width in the second direction; and
a ratio of the first distance to the second distance ranges between 0.4 and 0.75, and a ratio of the preset width to the second distance ranges between 0.5 and 0.75.

In an embodiment of the disclosure, the plurality of the first opening groups includes a plurality of first sub-groups and a plurality of second sub-groups arranged alternately along the second direction; and
wherein hole buffer sub-part and the hole end parts in each of the first sub-groups are respectively disposed in alignment in the second direction, and hole buffer sub-parts and the hole end parts in each of the second sub-groups are respectively disposed in alignment in the second direction.

In an embodiment of the disclosure, the bending area includes a first bending sub-area, second bending sub-areas between the first bending sub-area and the non-bending sub-areas, and a spacing area between the first bending sub-area and the second bending sub-areas; and
wherein the plurality of the first opening groups and the quasi-bending line are located at the first bending sub-area; the support layer further includes a plurality of second openings disposed at the second bending sub-areas, and a depth of each of the second openings is less than a depth of each of the first openings in a thickness direction of the support layer.

In an embodiment of the disclosure, the display panel is configured to switch between a flattened mode and a folded mode; when the display panel is switched to the folded mode, the panel body and the support layer are bent along the quasi-bending line, and a bending radius of the support layer is less than a bending radius of the panel body.

According to an above-mentioned purpose of the disclosure, an embodiment of the disclosure further provides a display device, the display device includes a display panel, the display panel includes a bending area and non-bending areas adjoined with the bending area, and the bending area is defined with a quasi-bending line extending along a first direction;
wherein the display panel further includes:
a panel body; and
a support layer, disposed on a side of the panel body, wherein the support layer includes a plurality of first opening groups disposed at the bending area and arranged along a second direction, a preset angle is defined between the first direction and the second direction, and each of the first opening groups includes a plurality of first openings arranged along the first direction and disposed at intervals;
wherein each of the first openings includes a hole body part and hole end parts connected to two opposite ends of the hole body part in the first direction; the hole body part includes at least one hole buffer sub-part and at least one hole connection sub-part which is connected to the hole end parts and the hole buffer sub-part in the first direction, and a width of the hole connection sub-part is less than a width of each of the hole end parts and a width of the hole buffer sub-part in the second direction; and
wherein the hole buffer sub-part in one of two adjacent first opening groups of the first opening groups and a side of the hole connection sub-part close to a corresponding one of the hole end parts in the other one of the two adjacent first opening groups of the first opening groups are disposed in alignment along the second direction.

In an embodiment of the disclosure, the support layer further includes a spacing part disposed between two adjacent first openings of the first openings in one of the first opening groups, and the hole buffer sub-part and the spacing part are staggered along the second direction.

In an embodiment of the disclosure, the hole body part includes two hole buffer sub-parts arranged between two hole end parts along the first direction, and a hole middle sub-part connected between the two hole buffer sub-parts in the first direction, and a width of the hole middle sub-part is less than the width of each of the hole end parts and a width of each of the hole buffer sub-parts in the second direction;
wherein the hole middle sub-part in the one of two adjacent first opening groups and the spacing part of in the other one of the two adjacent first opening groups are disposed in alignment along the second direction.

In an embodiment of the disclosure, each of the first openings includes the two hole end parts, two hole connection sub-parts, the two hole buffer sub-parts, and the hole middle sub-part, and the two hole buffer sub-parts are connected to two opposite sides of the hole middle sub-part, respectively, the two hole connection sub-parts are connected to two opposite sides of the two hole buffer sub-parts away from the hole middle sub-part, respectively, and the two hole end parts are connected to two opposite sides of the two hole connection sub-parts away from the hole middle sub-part, respectively.

In an embodiment of the disclosure, the two hole end parts, the two hole connection sub-parts, and the two hole buffer sub-parts are symmetrically disposed relative to the hole middle sub-part, respectively.

In an embodiment of the disclosure, a width of a side of the hole buffer sub-part close to the hole middle sub-part decreases gradually along a direction of the hole buffer sub-part close to the hole middle sub-part, and a width of a side of the hole buffer sub-part close to the hole connection sub-part decreases gradually along a direction of the hole buffer sub-part away from the hole middle sub-part, and a width of a side of each of the hole end parts close to the hole connection sub-part gradually decreases along a direction of each of the hole end parts close to the hole connection sub-part.

In an embodiment of the disclosure, a ratio of the width of each of the hole end parts in the second direction to a width of the hole connection sub-part in the second direction ranges between 1.5 and 2.5; and
a ratio of the width of each of the hole end parts in the second direction to the width of the hole middle sub-part in the second direction ranges between 1.5 and 2.5.

In an embodiment of the disclosure, a first distance is defined between the hole buffer sub-part in the one of two adjacent first opening groups and the hole connection sub-part in the other one of the two adjacent first opening groups in the second direction, a second distance is defined between the hole connection sub-part in the one of two adjacent first opening groups and the hole connection sub-part in the other one of the two adjacent first opening groups in the second direction, and the hole connection sub-part is defined with a preset width in the second direction; and
a ratio of the first distance to the second distance ranges between 0.4 and 0.75, and a ratio of the preset width to the second distance ranges between 0.5 and 0.75.

In an embodiment of the disclosure, the plurality of the first opening groups includes a plurality of first sub-groups and a plurality of second sub-groups arranged alternately along the second direction; and
wherein hole buffer sub-part and the hole end parts in each of the first sub-groups are respectively disposed in alignment in the second direction, and hole buffer sub-parts and the hole end parts in each of the second sub-groups are respectively disposed in alignment in the second direction.

### Beneficial Effects

Compared with the prior art, the hole body part provided by the disclosure is provided with the hole buffer sub-part, the width of the hole buffer sub-part and the width of the hole end part are both greater than the width of the hole connection sub-part, and the hole buffer sub-part in one of two adjacent first opening groups and the side of the hole connection sub-part close to the hole end part in the other one of the two adjacent first opening groups are disposed in alignment along the second direction. Through the above-mentioned design, the hole buffer sub-part can play a stress buffering role on a side of an adjacent hole connection sub-part close to the hole end part in the second direction, so as to reduce probability of arching and fracture of the side of the hole connection sub-part close to the hole end part due to torsional stress concentration, thereby improving flatness of the display panel at a bending position to improve a bending performance and yield of the display panel.

### BRIEF DESCRIPTION OF THE DRAWINGS

Technical solutions and other beneficial effects of the disclosure will be apparent through detailed description of specific implementation of the disclosure in combination with attached drawings.

FIG. 1 is a schematic structural diagram of a plurality of first opening groups provided by an embodiment of the disclosure.

FIG. 2 is a schematic structural diagram of a display panel provided by an embodiment of the disclosure.

FIG. 3 is a schematic structural diagram of the display panel provided by the embodiment of the disclosure in a folded mode.

FIG. 4 is a simulation diagram of bending stress of a support layer provided by an embodiment of the disclosure.

FIG. 5 is a schematic structural diagram of a first opening group provided by an embodiment of the disclosure.

FIG. 6 is a schematic enlarged structural diagram at a position A in FIG. 5.

FIG. 7 is a curve diagram of one size of a first opening and bending stress of the support layer provided by an embodiment of the disclosure.

FIG. 8 is a curve diagram of the other one size of the first opening and the bending stress of the support layer provided by the embodiment of the disclosure.

FIG. 9 is a curve diagram of one size of the first opening and bending rebound forces of the support layer provided by the embodiment of the disclosure.

FIG. 10 is a curve diagram of the other one size of the first opening and bending rebound forces of the support layer provided by the embodiment of the disclosure.

FIG. 11 is a schematic plane structural diagram of the support layer provided by the embodiment of the disclosure.

### DETAILED DESCRIPTION

In combination with drawings in the embodiments of the disclosure, technical solutions in the embodiments of the disclosure will be described clearly and completely. Obviously, the described embodiments are only part of the embodiments of the disclosure, not all of them. Based on the embodiments of the disclosure, all other embodiments obtained by those skilled in the art without creative effort belong to a scope of the disclosure.

The following disclosure provides many different embodiments or examples to realize different structures of the disclosure. In order to simplify the disclosure, components and arrangement of specific examples are described below. Of course, they are only examples and are not intended to limit the disclosure. In addition, the disclosure can repeat reference numbers and/or reference letters in different examples. This repetition is for a purpose of simplification and clarity, and does not indicate relationships between various embodiments and/or arrangement discussed. In addition, the disclosure provides examples of various specific processes and materials, but person having ordinary skill in the art can be aware of the disclosure of other processes and/or use of other materials.

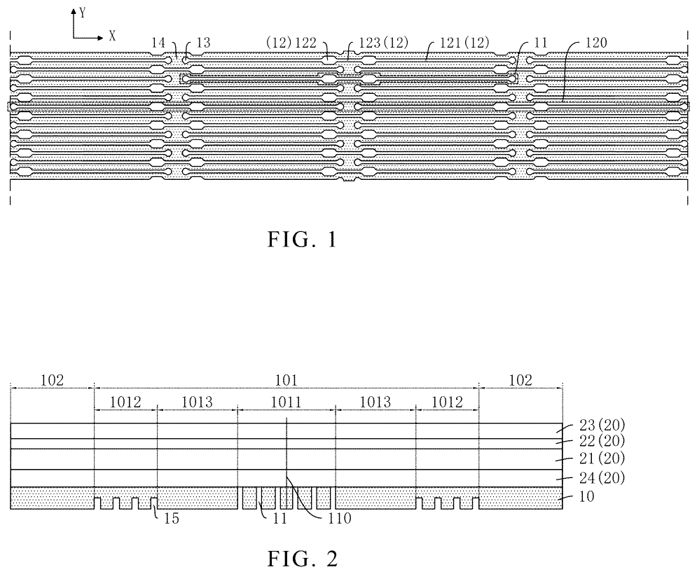

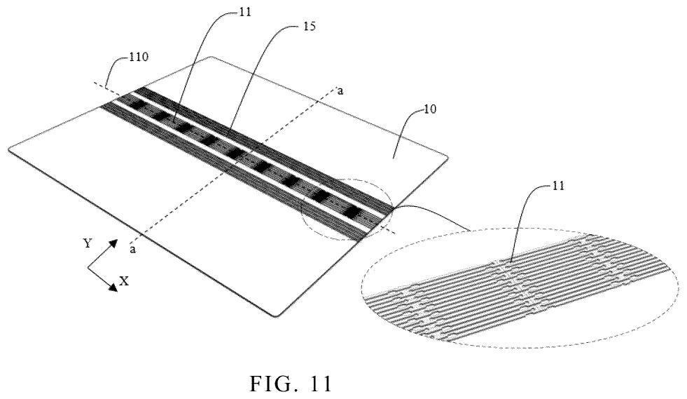

An embodiment of the disclosure provides a display panel. Please refer to FIG. 1, FIG. 2, and FIG. 11. A diagram of a support layer 10 in FIG. 2 is a schematic sectional structural diagram taken along a line aa in FIG. 11. The display panel includes a bending area 101 and non-bending areas 102 adjoined with the bending area 101. The bending area 101 is defined with a quasi-bending line 110 extending along a first direction X.

The display panel also includes a panel body 21 and the support layer 10. The support layer 10 is disposed on a side of the panel body 21, and includes a plurality of first opening groups 120 disposed at the bending area 101 and arranged along a second direction Y. A preset angle is defined between the first direction X and the second direction Y. The first opening group 120 includes a plurality of first openings 11 arranged along the first direction X and disposed at intervals.

Further, the first opening 11 includes a hole body part 12 and hole end parts 13 connected to two opposite ends of the hole body part 12 in the first direction X. The hole body part 12 includes a hole buffer sub-part 122 and a hole connection sub-part 121 which is connected to the hole end part 13 and the hole buffer sub-part 122 in the first direction X. A width of the hole connection sub-part 121 is less than a width of the hole end part 13 and a width of the hole buffer sub-part 122 in the second direction Y.

The hole buffer sub-part 122 in one of two adjacent first opening groups 120 and a side of the hole connection sub-part 121 close to the hole end part 13 in the other one of the two adjacent first opening groups 120 are disposed in alignment in the second direction Y.

In a process of implementation and application, since stress may concentrate at an end part of the first opening 11 in a bending process of the first opening 11, a width of the hole end part 13 is generally designed to be greater than a width of the hole connection sub-part 121 in the second direction Y, so that stress at a position the hole end part 13 located can be released. However, the above-mentioned design leads to a phenomenon of torsional stress concentration at a side of the hole connection sub-part 121 close to the hole end part 13 because of a width change, resulting in fracture of the side of the hole connection sub-part 121 close to the hole end part 13 due to torsional stress. By designing the hole body part 12 provided with the hole buffer sub-part 122, the width of the hole buffer sub-part 122 being greater than the width of the hole connection sub-part 121, and the hole buffer sub-part 122 in one of two adjacent first opening groups 120 and the side of the hole connection sub-part 121 close to the hole end part 13 in the other one of the two adjacent first opening groups 120 being disposed in alignment along the second direction Y, the hole buffer sub-part 122 provided by the embodiment of the disclosure can play a stress buffering role on a side of an adjacent hole connection sub-part 121 close to the hole end part 13 in the second direction Y, so as to reduce probability of arching and fracture of the side of the hole connection sub-part 121 close to the hole end part 13 due to torsional stress concentration, thereby improving flatness of the display panel at a bending position to improve a bending performance and yield of the display panel.

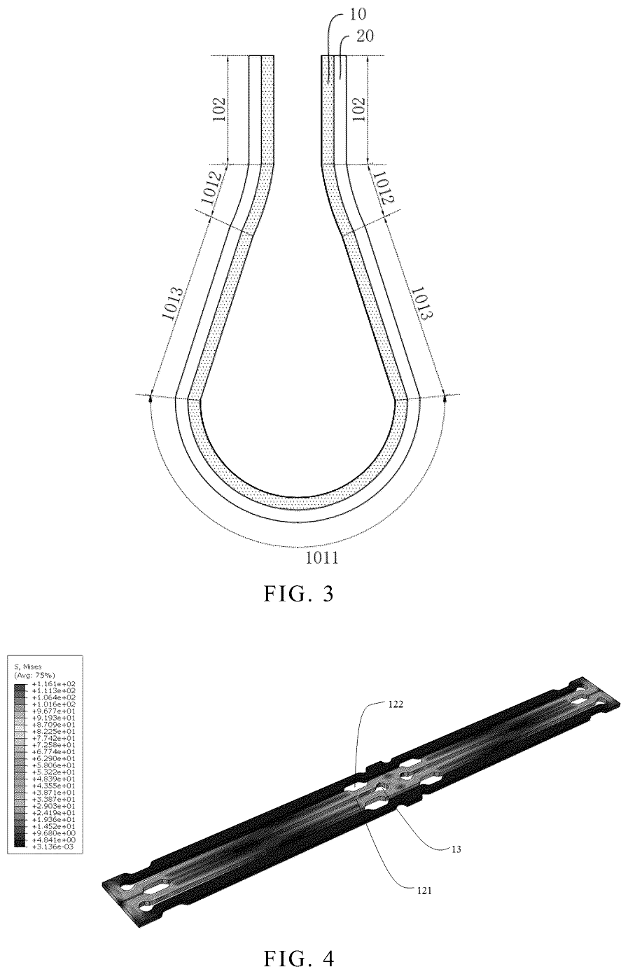

Specifically, please continue to refer to FIG. 1, FIG. 2, and FIG. 3. The display panel provided by the embodiment of the disclosure includes the panel body 21, a polarizer 22 disposed on a light-emitting side of the panel body 21, a cover plate 23 disposed on a side of the polarizer 22 away from the panel body 21, a back plate 24 disposed on a back side of the panel body 21, and the support layer 10 disposed on a side of the back plate 24 away from the panel body 21.

It should be noted that the display panel provided by the embodiment of the disclosure includes a flattened mode and a folded mode. In the flattened mode of the display panel, a functional film layer 20 including the panel body 21, the polarizer 22, the cover plate 23, and the back plate 24, and the support layer 10 are in the flattened mode, as shown in FIG. 2. In the folded mode of the display panel, both the functional film layer 20 and the support layer 10 are in the folded mode, and can be in an out-folded state, that is, the support layer 10 is on an inner side of the display panel and the functional film layer 20 is on an outer side of the display panel, as shown in FIG. 3. When the display panel is switched to the folded mode, a bending radius of the support layer 10 is less than a bending radius of the functional film layer 20 and a bending radius of the panel body 21.

In an embodiment, a material of the support layer 10 may include any of steel sheet, titanium alloy, carbon fiber, and a polymer composite. Here, only for example, without specific limitation.

The support layer 10 can support the functional film layer 20 such as the panel body 21. In the embodiment of the disclosure, the support layer 10 is patterned to improve a bending performance of the support layer 10.

Specifically, the support layer 10 includes the bending area 101 and the non-bending areas 102 adjoined with the bending area 101. The bending area 101 includes the quasi-bending line 110 extending along the first direction X. That is, when the display panel is switched to the folded mode, the support layer 10 is bent along the quasi-bending line 110.

The support layer 10 includes a plurality of first opening groups 120 disposed at the bending area 101 and arranged along the second direction Y. Each first opening group 120 includes the plurality of first openings 11 arranged along the first direction X and disposed at intervals. That is, the support layer 10 provided by the embodiment of the disclosure is provided with the plurality of first openings 11, so as to effectively improve the bending performance of the support layer 10.

In an embodiment, the first direction X is perpendicular to the second direction Y.

Further, each first opening 11 includes the hole body part 12 and the hole end parts 13 connected to two opposite ends of the hole body part 12 in the first direction X. In each first opening 11, the hole body part 12 includes two hole buffer sub-parts 122 arranged between two hole end parts 13 in the first direction X, the hole connection sub-part 121 connected between the hole end part 13 and the hole buffer sub-part 122 in the first direction X, and a hole middle sub-part 123 connected between the two hole buffer sub-parts 122 in the first direction X.

Correspondingly, each first opening 11 includes two hole end parts 13, two hole connection sub-parts 121, two hole buffer sub-parts 122, and one hole middle sub-part 123. In each first opening 11, the two hole buffer sub-parts 122 are connected to two opposite sides of the hole middle sub-part 123, respectively, the two hole connection sub-parts 121 are connected to two opposite sides of the two hole buffer sub-parts 122 away from the hole middle sub-part 123, respectively, and the two hole end parts 13 are connected to two opposite sides of the two hole connection sub-parts 121 away from the hole middle sub-part 123, respectively.

In an embodiment, the two hole end parts 13, the two hole connection sub-parts 121, and the two hole buffer sub-parts 122 are symmetrically disposed relative to the hole middle sub-part 123, respectively.

Further, the plurality of first opening groups 120 include a plurality of first sub-groups and a plurality of second sub-groups alternately arranged along the second direction Y. One second sub-group is disposed between two adjacent first sub-groups along the second direction Y, and one first sub-group is disposed between two adjacent second sub-groups along the second direction Y. The hole buffer sub-parts 122 and the hole end parts 13 of the first sub-groups are respectively disposed in alignment along the second direction Y. The hole buffer sub-parts 122 and the hole end parts 13 of the second sub-groups are respectively disposed in alignment along the second direction Y.

It should be noted that the hole end part 13 is located at two ends of the hole body part 12, that is, at two ends of the first opening 11. The width of the hole end part 13 is greater than the width of the hole connection sub-part 121 in the second direction Y. Stress concentration may occur at the two ends of the first opening 11 in a bending process, by increasing the width of the hole end part 13 in the embodiment of the application, ability of buffering stress generated in the two ends of the first opening 11 can be improved, thereby improving the bending performance of the support layer 10.

A ratio of the width of the hole end part 13 in the second direction Y to the width of the hole connection sub-part 121 in the second direction Y ranges between 1.5 and 2.5.

Further, because the width of the hole end part 13 in the second direction Y is greater than the width of the hole connection sub-part 121 in the second direction Y, a phenomenon of torsional stress concentration at a side of the hole connection sub-part 121 close to the hole end part 13 may occur in a bending process of the support layer 10, resulting in fracture of the side of the hole connection sub-part 121 close to the hole end part 13 due to torsional stress. Therefore, a simulation test provided by the embodiment of the disclosure is performed on the support layer 10 in an out-folded state, to obtain a simulation diagram of bending stress of the support layer 10, as shown in FIG. 4. As can be seen from FIG. 4, when the support layer 10 is bent, torsional stress mainly concentrates on the side of the hole connection sub-part 121 close to the hole end part 13.

Therefore, in the embodiment of the disclosure, the first opening 11 is designed to be provided with the hole buffer sub-part 122 defined with a greater width, the width of the hole buffer sub-part 122 is designed to be greater than the width of the hole connection sub-part 121 in the second direction Y, and the hole buffer sub-part 122 in one of two adjacent first opening groups 120 and the side of the hole connection sub-part 121 in the other one of the two adjacent first opening groups 120 close to the hole end part 13 are designed to be disposed in alignment along the second direction Y, so as to solve the above-mentioned problems. Through the above-mentioned design, the hole buffer sub-part 122 can play a stress buffering role on a side of an adjacent hole connection sub-part 121 close to the hole end part 13 in the second direction Y, so as to reduce probability of arching and fracture of the side of the hole connection sub-part 121 close to the hole end part 13 due to torsional stress concentration. In addition, when a part of the support layer 10 between the hole buffer sub-part 122 and the adjacent hole connection sub-part 121 in the second direction Y deforms because of bending, the part of the support layer 10 can deform towards the hole buffer sub-part 122, which can reduce probability of arching of the part of the support layer 10 between the hole buffer sub-part 122 and the hole connection sub-part 121 towards a side of the panel body 21 in a bending process, so as to improve flatness of a bending position of the display panel in the folded mode, thereby improving a bending performance and a display effect of the display panel.

In the embodiment of the disclosure, the support layer 10 includes a spacing part 14 disposed between two adjacent first openings 11 of the first opening group 120. A position the spacing part 14 located is a position of the support layer 10 where no holes are dug. The spacing part 14 can play a role in improving a support performance of the support layer 10.

Further, the hole middle sub-part 123 of the first opening 11 is located between the two hole buffer sub-parts 122. A width of the hole middle sub-part 123 is less than the width of the hole buffer sub-part 122 and the width of the hole end part 13 in the second direction Y. The hole middle sub-part 123 in one of two adjacent first opening groups 120 and the spacing part 14 in the other one of the two adjacent first opening groups 120 are disposed in alignment along the second direction Y, and the hole buffer sub-part 122 in one of two adjacent first opening groups 120 and the spacing part 14 in the other one of the two adjacent first opening groups 120 are staggered along the second direction Y. The width of the hole middle sub-part 123 is less than widths of other parts of the first opening 11 in the second direction Y, correspondingly, the width of the spacing part 14 in the second direction Y can be kept greater to improve the support performance of the support layer 10. At the same time, in the embodiment of the disclosure, increase of the width of the hole end part 13 and the width of the hole buffer sub-part 122 can improve a bending performance of the support layer 10.

A ratio of the width of the hole end part 13 in the second direction Y to the width of the hole middle sub-part 123 in the second direction Y ranges between 1.5 and 2.5.

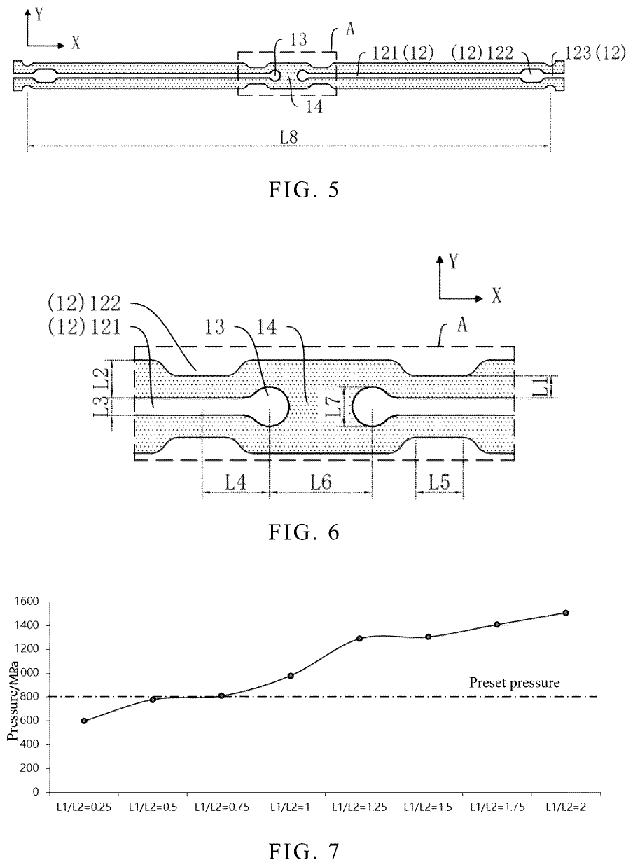

Please refer to FIG. 1, FIG. 5, and FIG. 6, and FIG. 6 is a schematic enlarged structural diagram at a position of A in FIG. 5. A first distance L1 is defined between the hole buffer sub-part 122 in one of two adjacent first opening groups 120 and the hole connection sub-part 121 in the other one of the two adjacent first opening groups 120 in the second direction Y. A second distance L2 is defined between the hole connection sub-part 121 in one of two adjacent first opening groups 120 and the hole connection sub-part 121 in the other one of the two adjacent first opening groups 120 in the second direction Y. The hole connection sub-part 121 is defined with a third distance L3 in the second direction Y. Overall bending stress of the support layer 10 is mainly determined by a ratio of the first distance L1 to the second distance L2 and a ratio of the third distance L3 to the second distance L2 in the embodiment of the disclosure. When factors such as bending stress of the support layer 10 is considered, a rebound force of the support layer 10 may also be necessarily to be considered. If the rebound force of the support layer 10 is too large, a module is not easy to be bent, resulting in the display panel being not easy to reach a bending closed state in the folded mode, so that it is necessary to reduce a negative effect caused by the rebound force through auxiliary functions such as magnet adsorption. If the rebound force and supportability of the support layer 10 are insufficient, the display panel is prone to collapse at the bending area 101.

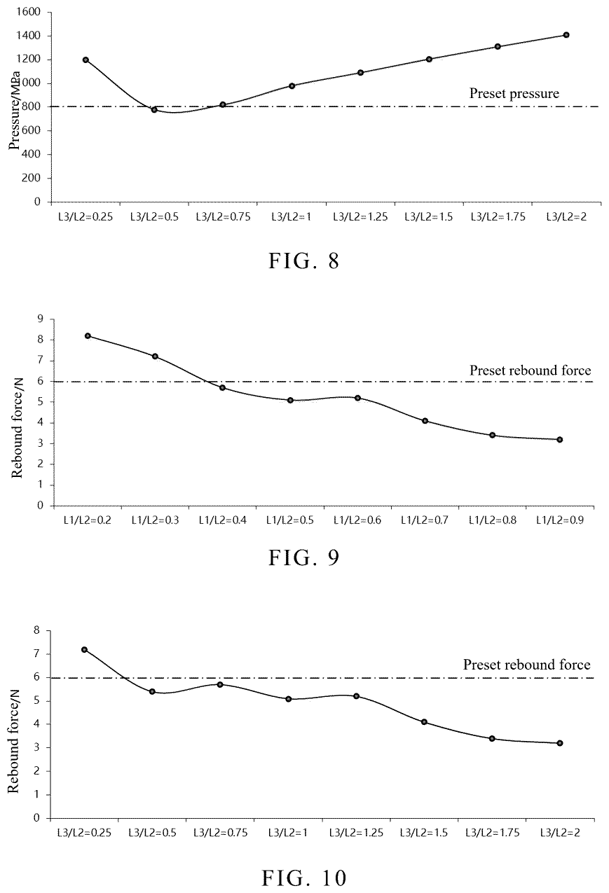

Therefore, the bending stress and the rebound force of the support layer 10 are verified to obtain appropriate ranges of the ratio of the first distance L1 to second distance L2 and the ratio of the third distance L3 to the second distance L2 in the embodiment of the disclosure. Stainless steel is selected as a material of the support layer 10 to obtain curve diagrams shown in FIG. 7, FIG. 8, FIG. 9, and FIG. 10. Preset pressures in FIG. 7 and FIG. 8 are corresponding to fatigue strength of the support layer 10, and are all 800 MPa. When a pressure of the support layer 10 exceeds the preset pressure in a bending process, undesirable phenomena such as fracture may occur on the support layer 10. Further, preset rebound forces in FIG. 9 and FIG. 10 are all 6 N. When a rebound force of the support layer 10 exceeds the preset rebound force in a bending process, the display panel is not easy to be bent, and it is not easy to reach a bending closed state when the display panel is bent.

It can be seen from FIG. 7 and FIG. 9 that when the ratio of the first distance L1 to the second distance L2 is designed to range between 0.4 and 0.75, the pressure of the support layer 10 in the bending process is within a range of the preset pressure, and the rebound force of support layer 10 in the bending process is within a range of the preset rebound force. Similarly, it can be seen from FIG. 8 and FIG. 10 that when the ratio of the third distance L3 to the second distance L2 is designed to range between 0.5 and 0.75, the pressure of the support layer 10 in the bending process is within a range of the preset pressure, and the rebound force of support layer 10 in the bending process is within a range of the preset rebound force.

In an embodiment, a width of a side of the hole buffer sub-part 122 close to the hole middle sub-part 123 decreases gradually along a direction of the hole buffer sub-part 122 close to the hole middle sub-part 123, a width of a side of the hole buffer sub-part 122 close to the hole connection sub-part 121 decreases gradually along a direction of the hole buffer sub-part 122 away from the hole middle sub-part 123, and a width of a side of the hole end part 13 close to the hole connection sub-part 121 decreases gradually along a direction of the hole end part 13 close to the hole connection sub-part 121. The above-mentioned design can play a transitional role between a part of the first opening 11 having a greater width and a part of the first opening 11 having a less width, thereby avoiding occurrence of adverse phenomena such as fracture or arching caused by a sharp change of bending stress of the support layer 10.

It should be noted that the hole buffer sub-part 122 and the hole end part 13 are staggered along the second direction Y in an embodiment of the disclosure, or a part of the hole buffer sub-part 122 where a width gradually decreases and a part of the hole end part 13 where a width gradually decreases are disposed in alignment along the second direction Y. Because the width of the hole buffer sub-part 122 and the width of the hole end part 13 are both greater, by designing the hole buffer sub-part 122 being staggered with the hole end part 13 in the second direction Y, the embodiment of the disclosure can avoid fracture of the support layer 10 due to an insufficient support performance caused by a small spacing between two adjacent first openings 11.

Optionally, a shape of the hole end part 13 may be a circular arc, a water drop-shaped, or other polygon, and a shape of the hole buffer sub-part 122 may be a polygon or a circular arc that is wide in a middle and gradually narrow on two sides.

The embodiment of the disclosure takes the shape of the hole end part 13 being a circular arc, and the shape of the hole buffer sub-part 122 being constituted of a rectangle in a middle and a shape with a width of two sides being gradually reduced as an example.

A fourth distance L4 is defined between a rectangular center of the hole buffer sub-part 122 and a circular center of the hole end part 13 in the first direction X. A distance of a rectangle part of the hole buffer sub-part 122 in the first direction X is defined as a fifth distance L5. The fourth distance L4 and the fifth distance L5 are main factors determining bending stress of the hole end part 13 of the first opening 11. If the fourth distance L4 and the fifth distance L5 are too small, the bending performance of the support layer 10 may be poor, making the first opening 11 easy to deform. If the fourth distance L4 and the fifth distance L5 are too large, supportability of the support layer 10 may be insufficient. Therefore, in the embodiment of the disclosure, the fourth distance L4 is designed to range between 0.8 mm and 1.2 mm, and the fifth distance L5 is designed to range between 0.4 mm and 0.8 mm to solve the above-mentioned problems.

Further, a sixth distance L6 is defined between circle centers of two adjacent hole end parts 13 in two adjacent first openings 11 of the first opening group 120. Similarly, if the sixth distance L6 is too small, the bending performance of the support layer 10 may be poor, and if the sixth distance L6 is too large, supportability of the support layer 10 may be insufficient. Therefore, the sixth distance L6 is designed to range between 0.3 mm and 0.6 mm to solve the above-mentioned problems.

In addition, a diameter of the hole end part 13, that is, a maximum distance of the hole end part 13 in the second direction Y is defined as a seventh distance L7. Similarly, If the seventh distance L7 is too small, a stress concentration effect generated at a position the hole end part 13 located may be obvious, and if the seventh distance L7 is too small, it is not conducive to bending of the support layer 10. Therefore, the seventh distance L7 is designed to range between 0.2 mm and 0.3 mm to solve the above-mentioned problems.

An eighth distance L8 is defined between circle centers of two hole end parts 13 of the first opening 11. If the eighth distance L8 is too small, the support layer 10 may not be bent easily, and if the eighth distance L8 is too large, rigidity and supportability of the support layer 10 may be reduced, making flatness of the support layer 10 and the functional film layer 20 poor after the two being attached. Therefore, the eighth distance L8 is designed to range between 4 mm and 6 mm to solve the above-mentioned problems.

In addition, in combination with FIG. 1, FIG. 2, FIG. 3, and FIG. 11, the bending area 101 of the display panel includes a first bending sub-area 1011, a second bending sub-area 1012 between the first bending sub-area 1011 and the non-bending sub-area 102, and a spacing area 1013 between the first bending sub-area 1011 and the second bending sub-area 1012. In the embodiment of the disclosure, the quasi-bending line 110 is located at the first bending sub-area 1011 and extends along the first direction X, and the plurality of first opening groups 120 are located at the first bending sub-area 1011.

When the display panel is switched to the folded mode, the display panel can be bent along the quasi-bending line 110. As can be seen from FIG. 3, a shape of a part of the display panel corresponding to the bending area 101 is a water drop-shape after being bent, and a part of the display panel corresponding to the non-bending area 102 is in a flattened state.

A shape of the display panel is circular arc after being bent at the first bending sub-area 1011, the display panel is in a straight state at the spacing area 1013, and a certain angle is defined between a part of the display panel at the spacing area 1013 and a part of the display panel at the non-bending area 102. The display panel has a certain radian at the second bending sub-area 1012 after being bent, so as to connect the part of the display panel at the spacing area 1013 and the part of the display panel at the non-bending area 102.

In an embodiment, the support layer 10 also includes a plurality of second opening groups disposed at the second bending sub-area 1012. The plurality of second opening groups are arranged along the second direction Y. Each second opening group includes a plurality of second openings 15 arranged along the first direction X and disposed at intervals, and the plurality of second openings 15 of two adjacent second opening groups are staggered or disposed in alignment, which is not limited here.

Specifically, an arrangement mode of the second opening groups and a structure of the second opening 15 may be designed with reference to an arrangement mode of the first opening groups 120 and a structure of the first opening 11 of the above-mentioned embodiment, respectively, or the second opening 15 may also be designed as a strip-type hole with a certain width in the second direction Y, and the plurality of second openings 15 of two adjacent second opening groups are staggered or disposed in alignment.

Because a bending degree of the support layer 10 at the second bending sub-area 1012 is less than a bending degree of the support layer 10 at the first bending sub-area 1011, by designing a depth of the second opening 15 being less than a depth of the first opening 11 in a thickness direction of the support layer 10, the bending performance of the support layer 10 provided by the embodiment of the disclosure can be improved, and at the same time, supportability of the support layer 10 can further be ensured.

In an embodiment, the first opening 11 may be a through-hole passing through the support layer 10, and the second opening 15 may only pass through a part of the support layer 10.

To sum up, by designing the hole body part 12 provided with the hole buffer sub-part 122, both the width of the hole buffer sub-part 122 and the width of the hole end part 13 being greater than the width of the hole connection sub-part 121, and the hole buffer sub-part 122 in one of two adjacent first opening groups 120 and the side of the hole connection sub-part 121 in the other one of the two adjacent first opening groups 120 close to the hole end part 13 being disposed in alignment along the second direction Y, the hole buffer sub-part 122 provided by the embodiment of the disclosure can play a stress buffering role on a side of an adjacent hole connection sub-part 121 close to the hole end part 13 in the second direction Y, so as to reduce probability of arching and fracture of the side of the hole connection sub-part 121 close to the hole end part 13 due to torsional stress concentration, thereby improving flatness of the display panel at a bending position to improve a bending performance and yield of the display panel.

In addition, an embodiment of the disclosure also provides a display device, and the display device includes a device body and the display panel described in the above-mentioned embodiment. The device body and the display panel are integrated as a whole.

The device body may include a middle frame, external components, hinges, etc. The display device may be a mobile phone, a flat panel, a television (TV), or other display terminals, which is not limited here.

In the above-mentioned embodiments, description of each embodiment has its own emphasis. For parts not detailed in an embodiment, please refer to relevant description of other embodiments.

The display panel and the display device provided by the embodiments of the disclosure are described in detail. In this paper, specific embodiments are adopted to illustrate a principle and implementation modes of the disclosure. The description of the above-mentioned embodiments is only used to help understand methods and a core idea of the disclosure. At the same time, for those skilled in the art, of the idea of the disclosure, there will be changes in specific implementation modes and a scope of the disclosure. In conclusion, contents of the specification should not be interpreted as a limitation of the disclosure.

1. A display panel, comprising a bending area and non-bending areas adjoined with the bending area, wherein the bending area is defined with a quasi-bending line extending along a first direction;
wherein the display panel further comprises:
a panel body; and
a support layer, disposed on a side of the panel body, wherein the support layer comprises a plurality of first opening groups disposed at the bending area and arranged along a second direction different from the first direction, and each of the first opening groups comprises a plurality of first openings arranged along the first direction and disposed at intervals;
wherein each of the first openings comprises a hole body part and hole end parts connected to two opposite ends of the hole body part in the first direction; the hole body part comprises at least one hole buffer sub-part and at least one hole connection sub-part which is connected to the hole end parts and the hole buffer sub-part in the first direction, and a width of the hole connection sub-part is less than a width of each of the hole end parts and a width of the hole buffer sub-part in the second direction; and
wherein the hole buffer sub-part in one of two adjacent first opening groups of the first opening groups and a side of the hole connection sub-part close to a corresponding one of the hole end parts in the other one of the two adjacent first opening groups of the first opening groups are disposed in alignment along the second direction.

2. The display panel of claim 1, wherein the support layer further comprises a spacing part disposed between two adjacent first openings of the first openings in one of the first opening groups, and the hole buffer sub-part in the one of two adjacent first opening groups and the spacing part in the other one of the two adjacent first opening groups are staggered along the second direction.

3. The display panel of claim 2, wherein the hole body part comprises two hole buffer sub-parts arranged between two hole end parts along the first direction, and a hole middle sub-part connected between the two hole buffer sub-parts in the first direction, and a width of the hole middle sub-part is less than the width of each of the hole end parts and a width of each of the hole buffer sub-parts in the second direction;
wherein the hole middle sub-part in the one of two adjacent first opening groups and the spacing part of in the other one of the two adjacent first opening groups are disposed in alignment along the second direction.

4. The display panel of claim 3, wherein each of the first openings comprises the two hole end parts, two hole connection sub-parts, the two hole buffer sub-parts, and the hole middle sub-part, and the two hole buffer sub-parts are connected to two opposite sides of the hole middle sub-part, respectively, the two hole connection sub-parts are connected to two opposite sides of the two hole buffer sub-parts away from the hole middle sub-part, respectively, and the two hole end parts are connected to two opposite sides of the two hole connection sub-parts away from the hole middle sub-part, respectively.

5. The display panel of claim 4, wherein the two hole end parts, the two hole connection sub-parts, and the two hole buffer sub-parts are symmetrically disposed relative to the hole middle sub-part, respectively.

6. The display panel of claim 3, wherein a width of a side of the hole buffer sub-part close to the hole middle sub-part decreases gradually along a direction of the hole buffer sub-part close to the hole middle sub-part, and a width of a side of the hole buffer sub-part close to the hole connection sub-part decreases gradually along a direction of the hole buffer sub-part away from the hole middle sub-part, and a width of a side of each of the hole end parts close to the hole connection sub-part gradually decreases along a direction of each of the hole end parts close to the hole connection sub-part.

7. The display panel of claim 3, wherein a ratio of the width of each of the hole end parts in the second direction to a width of the hole connection sub-part in the second direction ranges between 1.5 and 2.5; and
a ratio of the width of each of the hole end parts in the second direction to the width of the hole middle sub-part in the second direction ranges between 1.5 and 2.5.

8. The display panel of claim 1, wherein a first distance is defined between the hole buffer sub-part in the one of two adjacent first opening groups and the hole connection sub-part in the other one of the two adjacent first opening groups in the second direction, a second distance is defined between the hole connection sub-part in the one of two adjacent first opening groups and the hole connection sub-part in the other one of the two adjacent first opening groups in the second direction, and the hole connection sub-part is defined with a preset width in the second direction; and
a ratio of the first distance to the second distance ranges between 0.4 and 0.75, and a ratio of the preset width to the second distance ranges between 0.5 and 0.75.

9. The display panel of claim 1, wherein the plurality of the first opening groups comprises a plurality of first sub-groups and a plurality of second sub-groups arranged alternately along the second direction; and
wherein hole buffer sub-part and the hole end parts in each of the first sub-groups are respectively disposed in alignment in the second direction, and hole buffer sub-parts and the hole end parts in each of the second sub-groups are respectively disposed in alignment in the second direction.

10. The display panel of claim 1, wherein the bending area comprises a first bending sub-area, second bending sub-areas between the first bending sub-area and the non-bending sub-areas, and a spacing area between the first bending sub-area and the second bending sub-areas; and
wherein the plurality of the first opening groups and the quasi-bending line are located at the first bending sub-area; the support layer further comprises a plurality of second openings disposed at the second bending sub-areas, and a depth of each of the second openings is less than a depth of each of the first openings in a thickness direction of the support layer.

11. The display panel of claim 1, wherein the display panel is configured to switch between a flattened mode and a folded mode; when the display panel is switched to the folded mode, the panel body and the support layer are bent along the quasi-bending line, and a bending radius of the support layer is less than a bending radius of the panel body.

12. A display device, comprising a display panel, wherein the display panel comprises a bending area and non-bending areas adjoined with the bending area, and the bending area is defined with a quasi-bending line extending along a first direction;
wherein the display panel further comprises:
a panel body; and
a support layer, disposed on a side of the panel body, wherein the support layer comprises a plurality of first opening groups disposed at the bending area and arranged along a second direction different from the first direction, and each of the first opening groups comprises a plurality of first openings arranged along the first direction and disposed at intervals;
wherein each of the first openings comprises a hole body part and hole end parts connected to two opposite ends of the hole body part in the first direction; the hole body part comprises at least one hole buffer sub-part and at least one hole connection sub-part which is connected to the hole end parts and the hole buffer sub-part in the first direction, and a width of the hole connection sub-part is less than a width of each of the hole end parts and a width of the hole buffer sub-part in the second direction; and
wherein the hole buffer sub-part in one of two adjacent first opening groups of the first opening groups and a side of the hole connection sub-part close to a corresponding one of the hole end parts in the other one of the two adjacent first opening groups of the first opening groups are disposed in alignment along the second direction.

13. The display device of claim 12, wherein the support layer further comprises a spacing part disposed between two adjacent first openings of the first openings in one of the first opening groups, and the hole buffer sub-part in the one of two adjacent first opening groups and the spacing part in the other one of the two adjacent first opening groups are staggered along the second direction.

14. The display device of claim 13, wherein the hole body part comprises two hole buffer sub-parts arranged between two hole end parts along the first direction, and a hole middle sub-part connected between the two hole buffer sub-parts in the first direction, and a width of the hole middle sub-part is less than the width of each of the hole end parts and a width of each of the hole buffer sub-parts in the second direction;
wherein the hole middle sub-part in the one of two adjacent first opening groups and the spacing part of in the other one of the two adjacent first opening groups are disposed in alignment along the second direction.

15. The display device of claim 14, wherein each of the first openings comprises the two hole end parts, two hole connection sub-parts, the two hole buffer sub-parts, and the hole middle sub-part, and the two hole buffer sub-parts are connected to two opposite sides of the hole middle sub-part, respectively, the two hole connection sub-parts are connected to two opposite sides of the two hole buffer sub-parts away from the hole middle sub-part, respectively, and the two hole end parts are connected to two opposite sides of the two hole connection sub-parts away from the hole middle sub-part, respectively.

16. The display device of claim 15, wherein the two hole end parts, the two hole connection sub-parts, and the two hole buffer sub-parts are symmetrically disposed relative to the hole middle sub-part, respectively.

17. The display device of claim 14, wherein a width of a side of the hole buffer sub-part close to the hole middle sub-part decreases gradually along a direction of the hole buffer sub-part close to the hole middle sub-part, and a width of a side of the hole buffer sub-part close to the hole connection sub-part decreases gradually along a direction of the hole buffer sub-part away from the hole middle sub-part, and a width of a side of each of the hole end parts close to the hole connection sub-part gradually decreases along a direction of each of the hole end parts close to the hole connection sub-part.

18. The display device of claim 14, wherein a ratio of the width of each of the hole end parts in the second direction to a width of the hole connection sub-part in the second direction ranges between 1.5 and 2.5; and
a ratio of the width of each of the hole end parts in the second direction to the width of the hole middle sub-part in the second direction ranges between 1.5 and 2.5.

19. The display device of claim 12, wherein a first distance is defined between the hole buffer sub-part in the one of two adjacent first opening groups and the hole connection sub-part in the other one of the two adjacent first opening groups in the second direction, a second distance is defined between the hole connection sub-part in the one of two adjacent first opening groups and the hole connection sub-part in the other one of the two adjacent first opening groups in the second direction, and the hole connection sub-part is defined with a preset width in the second direction; and
a ratio of the first distance to the second distance ranges between 0.4 and 0.75, and a ratio of the preset width to the second distance ranges between 0.5 and 0.75.

20. The display device of claim 12, wherein the plurality of the first opening groups comprises a plurality of first sub-groups and a plurality of second sub-groups arranged alternately along the second direction; and
wherein hole buffer sub-part and the hole end parts in each of the first sub-groups are respectively disposed in alignment in the second direction, and hole buffer sub-parts and the hole end parts in each of the second sub-groups are respectively disposed in alignment in the second direction.
